(19) United States
(12) Patent Application Publication
(10) Pub. No.: US 2009/0242383 A1
(43) Pub. Date: Oct. 1, 2009

(54) APPARATUS AND METHOD FOR RF GROUNDING OF IPVD TABLE

(75) Inventors: Mirko Vukovic, Slingerlands, NY (US); James Grootegoed, Albany, NY (US); Rodney L. Robison, East Berne, NY (US); Toshiaki Fujisato, Tokyo (JP)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 12/059,649

(22) Filed: Mar. 31, 2008

(51) Int. Cl. C23C 14/34

(52) U.S. Cl. 204/164; 204/298.05

(57) ABSTRACT

An IPVD source assembly and method is provided for supplying and ionizing material for coating a semiconductor wafer. The assembly includes a process space containing a plasma and an electrostatic chuck moveable in to and out of the process space. The chuck is configured to support the semiconductor wafer. The assembly further includes a first shield in electrical communication with a table and a second shield. The first shield is configured to shield at least a portion of the electrostatic chuck when the chuck is in the process space and the second shield is configured to shield at least a portion of a space below the electrostatic chuck and the process space. A conducting element electrically connects the second shield to the table to substantially prevent a formation of a second plasma in the space below the electrostatic chuck and the process space.

### FIELD OF THE INVENTION

This invention relates to the Ionized Physical Vapor Deposition (IPVD) and, more particularly, to methods and apparatus for controlling the formation of plasmas in an IPVD system.

### BACKGROUND OF THE INVENTION

Ionized physical vapor deposition is a process which has particular utility in filling and lining high aspect ratio structures on silicon wafers. In ionized physical vapor deposition (IPVD) for deposition of thin coatings on semiconductor wafers, materials to be deposited are sputtered or otherwise vaporized from a source and then a substantial fraction of the vaporized material is converted to positive ions before reaching the wafer to be coated. This ionization is accomplished by a high-density plasma which is generated in a process gas in a vacuum chamber. The plasma may be generated by magnetically coupling RF energy through an RF powered excitation coil into the vacuum of the processing chamber. The plasma so generated is concentrated in a region between the source and the wafer. Then electrical/electrostatic forces are applied to the positive ions of coating material, such as by applying a negative bias on the wafer. Such a negative bias may either arise with the wafer electrically isolated by reason of the immersion of the wafer in a plasma or by the application of an RF voltage to the wafer. The bias causes ions of coating material to be accelerated toward the wafer so that an increased fraction of the coating material deposits onto the wafer at angles approximately normal to the wafer. This allows deposition of metal over wafer topography including in deep and narrow holes and trenches on the wafer surface, providing good coverage of the bottom and sidewalls of such topography.

Certain systems proposed by the assignee of the present application are disclosed in U.S. Pat. No. 5,878,423, U.S. Pat. No. 5,800,688, and U.S. Pat. No. 6,287,435, which are hereby expressly incorporated by reference herein. Such systems include a vacuum chamber which is provided with part of its outer wall formed of a dielectric material or window. An electrically conducting coil is disposed outside the dielectric window and generally concentric with the chamber. In operation, the coil is energized from a supply of RF power through a suitable matching system. The dielectric window allows the energy from the coil to be coupled into the chamber while isolating the coil from direct contact with the plasma. The window is protected from metal coating material deposition by an arrangement of shields, typically formed of metal, which are capable of passing RF electromagnetic fields into the interior region of the chamber, while preventing deposition of metal onto the dielectric window that would tend to form conducting paths for circulating currents generated by these electromagnetic fields. Such currents are undesirable because they lead to ohmic heating and to reduction of the electromagnetic coupling of plasma excitation energy from the coils to the plasma. The purpose of this excitation energy is to generate high-density plasma in the interior region of the chamber. A reduction of coupling causes plasma densities to be reduced and process results to deteriorate.

In such IPVD systems, material is, for example, sputtered from a target, which is charged negatively with respect to the plasma, usually by means of a DC power supply. The target is often of a planar magnetron design incorporating a magnetic circuit or other magnet structure which confines a plasma over the target for sputtering the target. The material arrives at a wafer supported on a wafer support or table to which RF bias is typically applied by means of an RF power supply and matching network.

In some configurations the IPVD system has a large volume under the process space, referred to as the pumping volume. This volume is separated from process space by a shield, which is grounded to the chamber by several bolts. In these configurations of the IPVD system, a faint parasitic plasma can sometimes be visually observed in the pumping volume during operation at high table positions and high ICP powers. This unwanted plasma may affect the upper plasma creating a potential source of non-uniformity from wafer to wafer.

What is needed is a method and apparatus to eliminate or reduce the possibility of striking a plasma in the pumping volume.

### SUMMARY OF THE INVENTION

In accordance with the present invention, high frequency modeling of the IPVD system has shown that the RF bias current return path can split in two arms. One return path is found to be directed to a lower shield and the table assembly. The other return path is found to exist along a chamber shield to surfaces of the pumping volume to the table bellows and to the table assembly. The very long return path for this second arm is determined to be highly inductive and creates a potential difference between the table shield and the lower shield. In presence of the ICP plasma, this potential difference can sustain the parasitic low density plasma in the pumping volume.

According to principles of the present invention, an IPVD source assembly is provided for supplying and ionizing material for coating a semiconductor wafer. The assembly includes a process volume containing a plasma and a wafer chuck moveable with a table in to and out of the process volume. The chuck is configured to support the semiconductor wafer.

In certain embodiments, the assembly may also include a first shield and a second shield. The first shield is in electrical communication with the table and configured to shield at least a portion of the electrostatic chuck when the chuck is in the process volume. The second shield is configured to shield at least a portion of a space below the electrostatic chuck and the process volume. A conducting element electrically connects to the second shield to the table to substantially prevent a formation of a second plasma in the space below the electrostatic chuck and the process volume. In some embodiments, the conducting element is a flexible strap. In a specific embodiment, the flexible strap is composed of copper and is about 100 mm wide.

Embodiments of the invention may contain multiple conducting elements. In these embodiments, a second conducting element electrically connects the second shield to the table to substantially prevent a formation of a second plasma in the space below the electrostatic chuck and the process volume with the second conducting element spaced apart from the first conducting element. In some embodiments with multiple conducting elements, the first and second conducting elements are symmetrically spaced apart.

Embodiments of the invention may utilize an RF coupling device to facilitate the first shield being in electrical communication with the table. In some embodiments, a base may additionally be in electrical communication with the table and the conducting element. In some of these embodiments, a support ring may be in electrical communication with the second shield and the conducting element where the support ring is spaced from the base. The support ring may also be in electrical communication with the second shield through an RF coupling device. In some particular embodiments, the support ring may maintain an electrical contact to facilitate the electrical communication by a force exerted from a spring. The spring may also be used to space the support ring from the base. In a specific embodiment, a third shield is in electrical communication with the base as well as being in electrical communication with an extension of the support ring through an RF coupling device.

An alternate embodiment of the IPVD source assembly includes a process volume containing a plasma, an electrostatic chuck moveable in to and out of the process volume, and a shield. The chuck is configured to support the semiconductor wafer. The shield is in electrical communication with a table and a chamber shield wall, which defines a portion of the process volume. The shield is configured move in to and out of the process volume with the electrostatic chuck. The shield is further configured to shield at least a portion of the electrostatic chuck when the chuck is in the process volume and at least a portion of a space below the electrostatic chuck and the process volume to substantially prevent a formation of a second plasma in the space below the electrostatic chuck and the process space. In some embodiments the shield may be in electrical communication with the table through an RF coupling device, and the shield may be in electrical communication with the chamber shield wall through an RF coupling device.

A method is provided for substantially preventing formation of a plasma in a pumping volume. A first shield is electrically connected to a table, and a second shield is also electrically connected to the table to substantially prevent a formation of a potential difference between the first and second shields. A first RF current return path forms along a surface of the first shield to a surface of the table. A second RF current return path forms along a surface of the second shield to a surface of the table. In some embodiments, the first current return path may form between surface of the first shield and the surface of the table through an RF coupling device. In other embodiments, the second current return path may form along a conducting element electrically connecting the surface of the second shield to the surface of the table. In some particular embodiments, the second current return path may further form along a surface of a base between the conducting element and the surface of the table.

In an alternate embodiment, the method provided for substantially preventing formation of a plasma in a pumping volume electrically connects a shield to a table and to a chamber shield wall to substantially prevent a formation of a potential difference between the shield and the shield wall. In this embodiment, the first RF current return path may form along a surface of the shield to a surface of the table, while a second RF current return path may form along a surface of the chamber shield wall the surface of the shield then to the surface of the table.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIG. 1 is cross section of an exemplary arrangement of an IPVD system consistent with embodiments of the invention.

FIG. 2 is a cross section of a portion of an embodiment of an IPVD system similar to that of FIG. 1.

FIG. 3 is a cross section of a portion of an alternate embodiment of an IPVD system similar to the embodiment in FIG. 2.

FIG. 4 is a cross section of a portion of an alternate embodiment of an IPVD system similar to the embodiment in FIG. 2.

FIG. 5 is a cross section of an alternate embodiment of a portion of an IPVD system similar to that of FIG. 1.

FIG. 6 is a cross section of an alternate embodiment of a portion of an IPVD system similar to that of FIG. 1.

### DETAILED DESCRIPTION

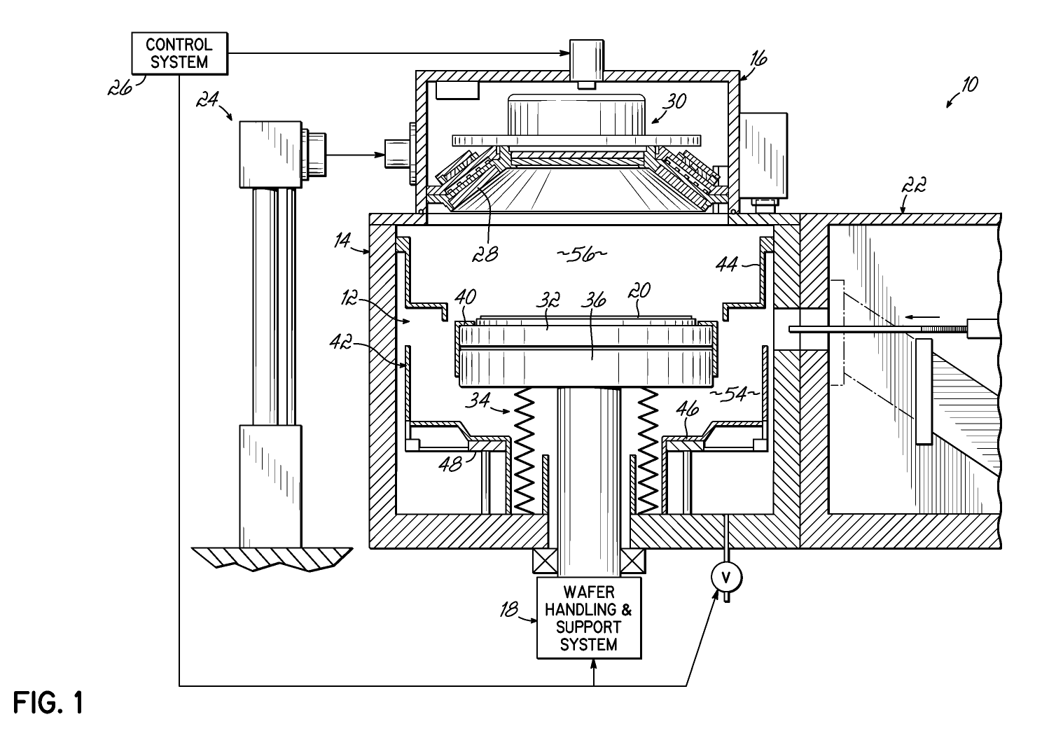

An exemplary ionized physical vapor deposition apparatus 10 is illustrated in FIG. 1. The IPVD apparatus 10 includes a vacuum (sputtering) chamber 12 bounded by a chamber wall assembly 14. The chamber 12 is provided with an ionized physical vapor deposition (IPVD) source 16 supplying coating material in vapor form into the volume of the sputtering chamber 12 and for ionizing the sputtering material vapor. The chamber 12 is further provided with an electrostatic chuck wafer support system 18 for holding wafers 20 during processing, a wafer handling system 22 for loading and unloading wafers 20 for processing, a vacuum and gas handling system (not shown) for evacuation of the chamber 12 to vacuum, an IPVD source hoist assembly 24 for removal and replacement of the target and for performing other servicing of the source, and a control system 26 which operates the other systems of the apparatus 10 in accordance with the methods and processes described herein and otherwise carried out with the apparatus 10.

The apparatus 10 is a serviceable module capable of providing features and operating conditions including, for example, the following: (1) base vacuum of less than about 10⁻⁸ Torr, (2) operating inert gas pressure of between about 30 and about 130 mTorr, (3) provision for reactive gas at partial pressure of about 0-50 mTorr, (4) variable substrate to target spacing of about 6 to about 9 inches, (5) electrostatic chucking with backside gas heating or cooling, and (6) shielding that restricts deposition to removable, cleanable components with surfaces having good adhesion of sputtered material to prevent particle generation.

The general concepts of the source 16 are described in U.S. Pat. No. 6,080,287, which is hereby expressly incorporated by reference herein. A particular implementation of the source 16 generally includes a target 28 of the conical target type laid out in the above referenced patent. Essentially the principle objectives of the source 16 include providing, for example, the following features and properties: (1) to require minimum operator effort and smallest possible set of tools to perform routine tasks, (2) to provide separation RF and DC power from water to the best extent possible, (3) to provide relative simplicity of design and operation; (4) to allow rapid repair or replacement of the source including quick replacement of the whole internal source assembly, (5) to provide modular internal assemblies, and (6) to maintain RF shielding integrity to prevent leakage of radiation into the operating environment.

The IPVD source 16 has an annular target 28 and an RF source assembly 30, which energizes an inductively coupled plasma in the process volume 56, opposite a 200 mm or 300 mm wafer 20, for example, which is to be mounted on an electrostatic chuck 32 of the wafer support system 18. The source 16 includes a source housing assembly including a source housing, which may be preferably an aluminum weldment. The source housing includes structure for mounting the working parts of the source 16 and rendering the source 16 capable of being mounted to source hoist assembly 24 for installation on, and removal from, the apparatus 10.

The electrostatic chuck assembly 34, which is part of the wafer support system 18, and the wafer handling system 22 cooperate in the transfer of wafers from one to the other. Chuck assembly 34 includes a wafer support, holder or chuck 32. A suitable chuck 32 may be obtained from INVAX Inc., Tokolo Co., Ltd., Kyocera or other sources. A fluid passage is provided for the passage of cooling fluid, for example a GALDEN brand perfluorinated fluid. The chuck 32 may have two embedded, electrically isolated, electrodes for the application of a chucking voltage, while RF bias can be applied to the chuck body by way of the electrostatic chuck electrodes. The RF is thereby coupled through to the embedded electrodes and thus to the wafer. All metal parts of the chuck are aluminum coated with a proprietary dielectric. Back side gas can be provided through a central hole. A thermocouple is mounted to the rear of the chuck.

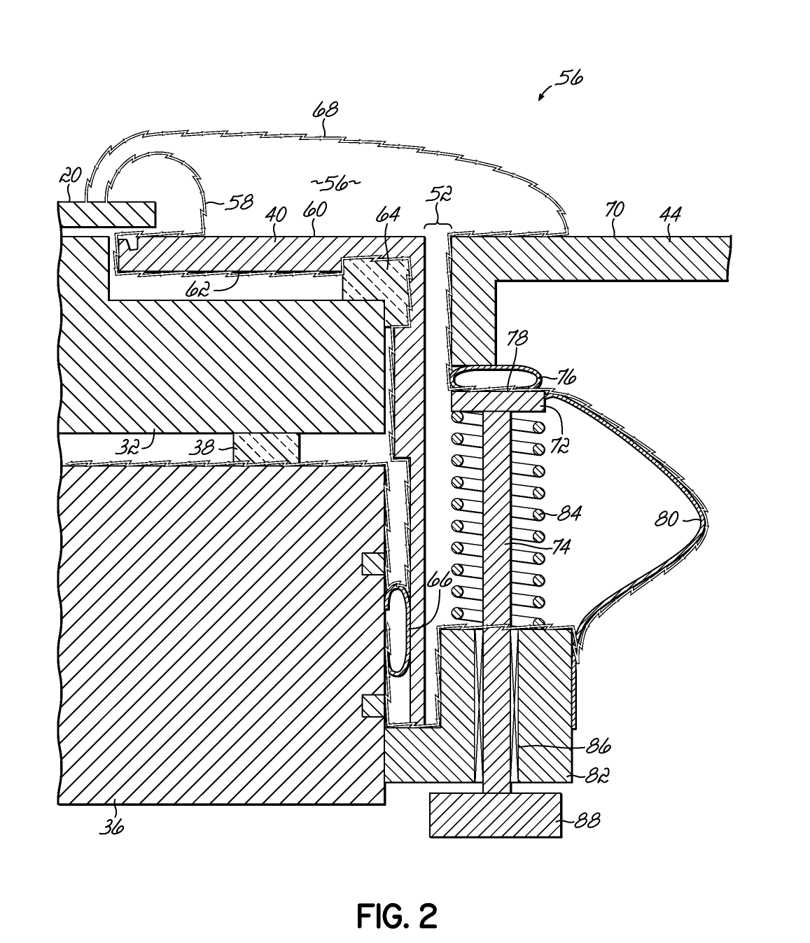

The chuck 32 has a number of counterbored holes and is mounted to the stainless steel table using screws; there are polyimide insulators, such as VESPEL®, that protect the chuck from damage by the screws and provide electrical isolation. An insulating block 38 isolates the chuck from the base (as best seen in the embodiment in FIG. 2).

A stainless table shield 40 rests on a step on the table 36 and shields the chuck 32 from metal deposition. An alternate system may include a grounded shield supplemented by a ring, which rests directly on the chuck. This ring may be made of aluminum or stainless steel and may or may not be coated with a dielectric material, possibly of high dielectric constant similar to that used in the chuck dielectric. This ring couples to the RF power that is applied to the chuck through the chuck dielectric. Advantages of this are that the shield can be in very close proximity to the chuck, thereby more effectively blocking metal deposition, and that RF power is applied to the ring causing it to attain the same bias as the wafer, which lessens the distortion of electric fields near the wafer edge. The ring overlaps but is separated from the grounded shield. This provides a convoluted path for metal deposition and keeps material from being deposited on the chuck. A sputter shield assembly 42 is provided. The shield assembly 42 may include five shields that are subject to removal and cleaning. These shields may include Faraday and dark space shields, the table shields 40, and two chamber shields 44 and 46. These chamber shields may be supported on an armature 48.

Referring now to the portion of an embodiment of a IPVD system 50 illustrated in FIG. 2, the gap 52 is small enough to dark space out the plasma formed above the wafer 20. In other words, the gap 52 is sufficiently small to prevent transmission of energy through the gap 52. The gap 52, however, does allow for the gas to flow into the pump volume 54 (FIG. 1). A potential difference across the gap, as described above, at high bias power can be sufficient to strike the low density plasma in the pump volume 54. In order to significantly reduce the chances of creating a potential difference between the table shield 40 and the chamber shield 44 resulting in a plasma in the pump volume, 54 the RF current paths are kept relatively short to avoid high inductances created by very long return paths creating the potential difference between the table shield 40 and the chamber shield 44.

In order to place the table shield 40 and chamber shield 44 at essentially the same potential, the shields are electrically connected as seen in FIG. 2. As discussed above, the RF current originating in the wafer support system and delivered to the wafer to create a bias, returns via two return paths. The first return path 58 starts as current leaves the wafer 20 and travels through the plasma in the process volume 56 contacting the table shield 40. The current travels along the outside surface 60 of the table shield 40 under the wafer 20 and then along the inner surface 62 of the table shield 40. The return current path 58 extends along the inner surface 62 of the table shield 40 past the chuck 32 which is insulated from the table 36 and table shield 40 by insulators 38 and 64 respectively.

The current path 58 then makes contact with the table through RF coupling device 66 at which point the current path travels along the table 36, which eventually contacts the return tube of the RF source. The RF coupling device 66 may include any type of RF coupling that is used to reduce or eliminate EMI. The RF coupling device 66 used in the present embodiment is a spring loaded type device having multiple contact surfaces to facilitate the return of the current between the table shield 40 and the table 36.

The second return current path 68 also leaves the wafer 20 and travels through the plasma in the process volume 56. The path 68 contacts the chamber shield 44 and proceeds along the outer surface 70 of the chamber shield 44 toward the table shield 40. In order to prevent the development of a potential difference between the table shield 40 and the chamber shield 44, the chamber shield is connected to a support ring 72 and slide rod 74 assembly by a second RF coupling device 76. The second return path 68 then proceeds through the RF coupling device 76 and along a top surface 78 of the support ring 72. A conducting element in the form of a flexible strap 80, such as a grounding strap, electrically connects the support ring 72 to a base 82, which is electrically coupled to the table 36 and completes the return path 68 similar to the first return path 58.

To facilitate loading and unloading of wafers 20, the components are moveable with respect to one another. For example, as the table 36, chuck 32, and table shield 40 are raised and lowered, the chamber shield 44 may also be adjusted. To maintain the electrical connections for the second return path 68, the support ring 72 is kept in contact with the RF coupling device 76 under a mechanical force produced by spring 84. The slide rod 74 slides through a bushing 86 in base 82. A stop ring 88 is provided to prevent the support ring 72 and slide rod 74 from becoming separated from the base 82.

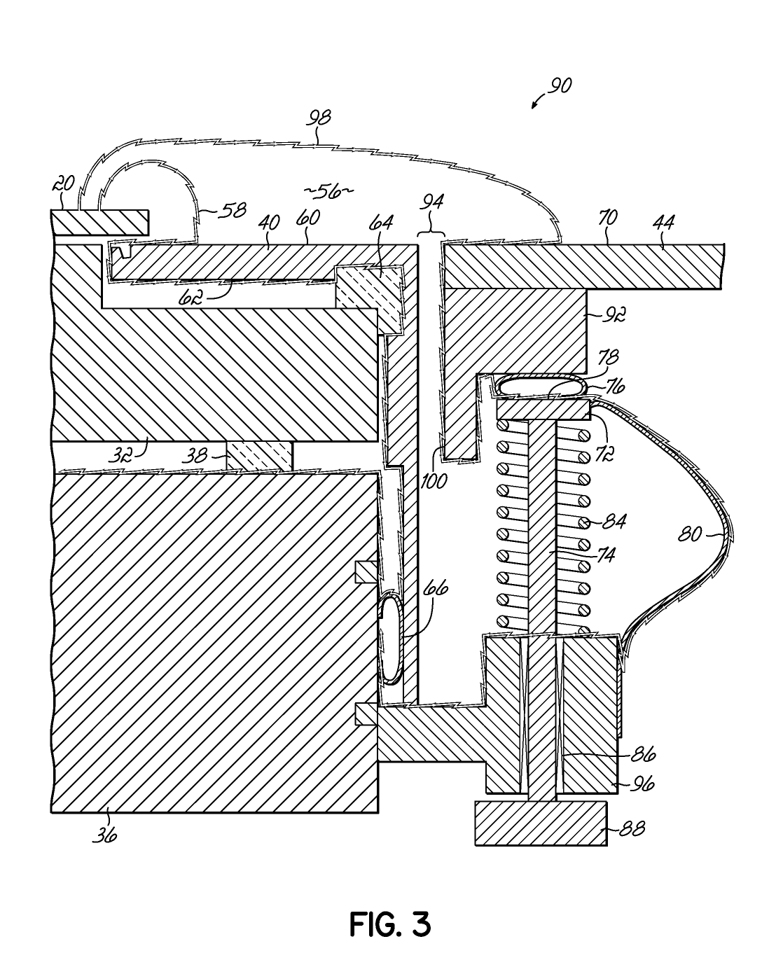

While the previous embodiment essentially eliminates the possibility of striking a plasma in the pumping volume 54, there is still a possibility of having metal deposition on the spring 84 due to the location of the spring relative to the gap 52. In order to avoid any unwanted deposition, a second embodiment of a portion of IPVD system 90 is illustrated in FIG. 3. In this embodiment, the chamber shield 44 contains extensions 92 to increase the aspect ratio of the gap 94 between the table shield 40 and the chamber shield 44. The spring contact assembly consisting of the RF coupling device 76, support ring 72, slide rod 74, stop ring 88 and spring 84 are located behind the shield extensions 92 in order to minimize any deposition on the spring 84 or other components. A base 96, similar to base 82 in the previous embodiment, extends to contact the table to facilitate an RF current return path.

In the embodiment in FIG. 3, the second return current path 98 leaves the wafer 20 and travels through the plasma in the process volume 56 similar to the embodiment in FIG. 2. The path 98 contacts the chamber shield 44 and proceeds along the outer surface 70 of the chamber shield 44 toward the table shield 40 and downward along the outer surface 100 of the shield extensions 92. In order to prevent the development of a potential difference between the table shield 40 and the chamber shield 44, the chamber shield is connected to the support ring 72 and slide rod 74 assembly by the RF coupling device 76. The second return path 98 then proceeds through the RF coupling device 76 and along the top surface 78 of the support ring 72. The flexible strap 80 electrically connects the support ring 72 to the base 96, which is electrically coupled to the table 36 and completes the return path 98 similar to the second return path 68 in the embodiment in FIG. 2.

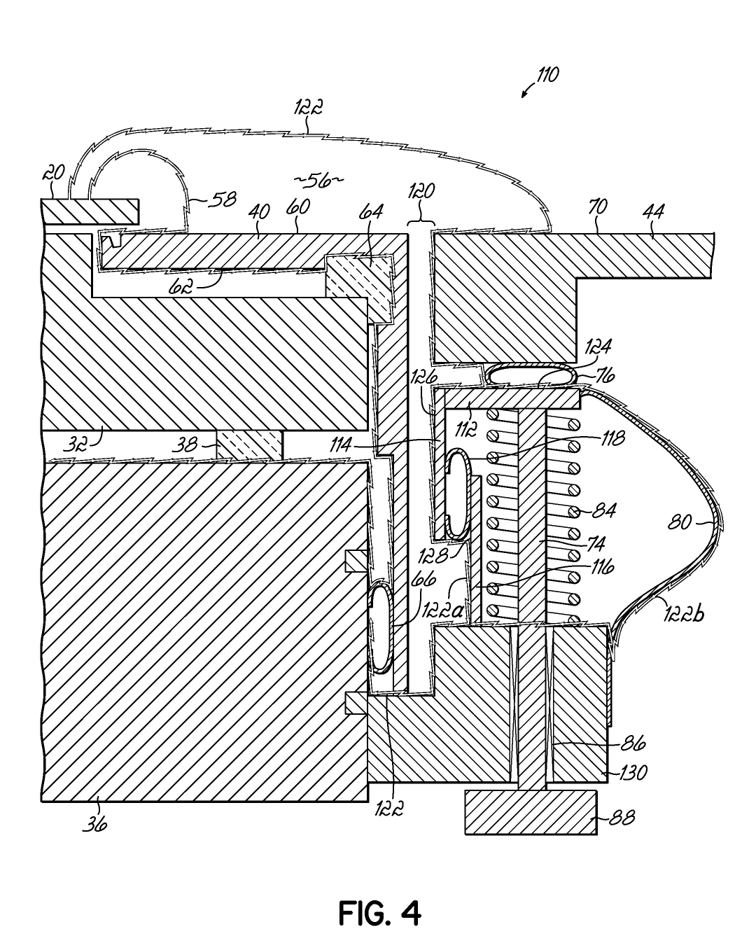

The embodiment in FIG. 4 shows a portion of an IPVD system 110 that extends the protection of the spring contact assembly from unwanted deposition by providing more structure around the spring. In this embodiment, a support ring 112 couples to an extension 114 to partially shield the spring 84. The support ring extension 114 is electrically coupled to a spring shield 116 by a third RF coupling device 118. The third RF coupling device 118 allows the support ring extension 114 to move relative to the spring shield 116 while maintaining an electrical connection. In conjunction with the high aspect ration gap 120, the additional structure of the support ring extension 114 and spring shield 116 substantially prevents unwanted deposition on the spring 84.

In the embodiment in FIG. 4, the second return current path 122 leaves the wafer 20 and travels through the plasma in the process volume 56 similar to the embodiments in FIG. 2 and FIG. 3. The path 122 contacts the chamber shield 44 and proceeds along the outer surface 70 of the chamber shield 44 toward the table shield 40. In order to prevent the development of a potential difference between the table shield 40 and the chamber shield 44, the chamber shield is electrically connected to the support ring 112 and slide rod 74 assembly by the RF coupling device 76. The second return path 122 then proceeds through the RF coupling device 76 and along the top surface 124 of the support ring 112. At this point the current may branch into one of two paths. The first path 122a travels along the top surface 124 toward the table shield 40 and then along an outer surface 126 of the support ring extension 114. The first branch 122a of the second return path 122 then proceeds through the third RF coupling device 118 to an outer surface 128 of the spring shield 116. The first branch 122a then travels along an extended base 130 back to the table 36. A second branch 122b of the second return path 122 travels along the surface 124 to the flexible strap 80, which connects the support ring 112 to the base 130 electrically coupled to the table 36. The flexible strap 80 completes the second branch 122b of the return path 122, meeting the first branch 122a and completes the return similar to the second return path 68 and 98 in the embodiments in FIG. 2 and FIG. 3.

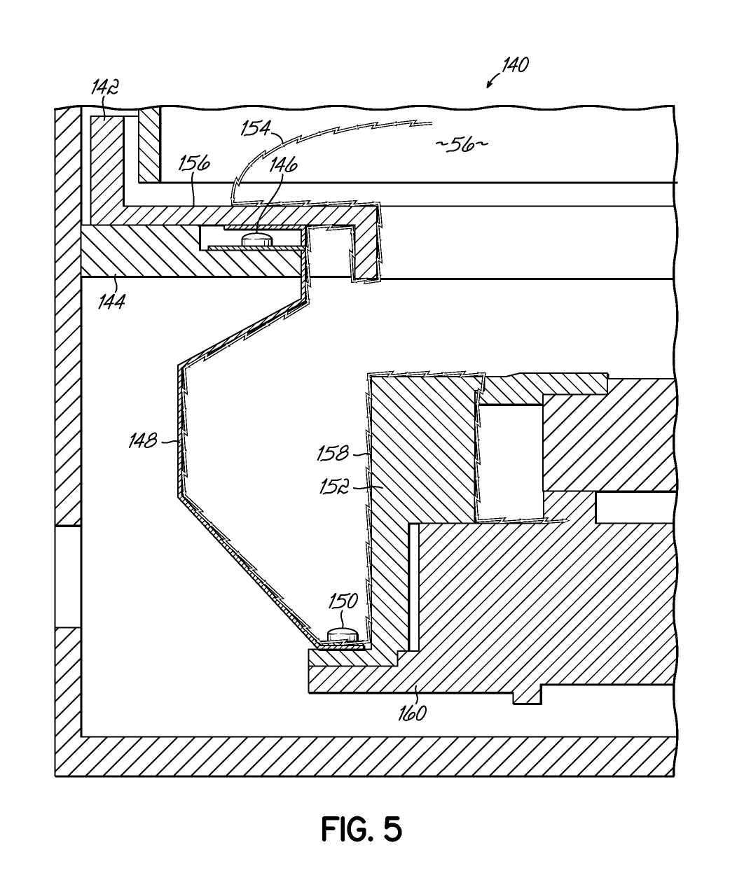

While the embodiments in FIGS. 2-4 substantially eliminate the creation of plasma in the pumping volume 54, the additional structure may not be necessary. The low density plasma tends to strike under high power, when the voltage potential is larger. The embodiment in FIG. 5 illustrates a portion of an IPVD system 140 using a ground strap to substantially prevent the creation of the low density plasma at higher power levels. In this embodiment, the lower chamber shield 142 is supported by a shield support 144. A bolt 146 on the shield support 144 electrically connects the chamber shield 142 and shield support 144 to one end of a flexible ground strap 148. The other end of the ground strap 148 is connected by bolt 150 to a table shield 152 to establish an electrical connection between the chamber shield 142 and the table shield 152. This electrical connection keeps that shields 142, 152 at the same potential, thus reducing the likelihood of striking a plasma in the pumping volume.

The ground strap 148 in this embodiment is approximately 100 mm wide and composed of copper, though other embodiments may use other conductive materials or other widths for the ground strap 148. Multiple ground straps 148 may be used around the shields 142, 152. The ground straps 148, should be symmetrically spaced to assist in reducing potential non-uniformities in the plasma. In the present embodiment, four symmetrically spaced ground straps 148 are used. Using four ground straps 148 allows the shields 142, 152 to be kept at essentially the same potential with minimal interference to the plasma and also allows access to the wafer 20 during loading and unloading operations.

The secondary current return path 154 in this embodiment again begins in the plasma in the process volume 56 as with the previous embodiments, and contacts an outer surface 156 of the lower chamber shield 142. The current contacts the ground strap 148, which is kept in contact with the chamber shield 142 by the bolt 146. The current then travels along the ground strap 148 to the table shield 152, where the ground strap 148 is kept in contact with table shield 152 by bolt 150. The current return path 154 then travels along an outer surface 158 of the table shield 152 until it contacts the table 160 where the current return is similar to the embodiments above. A secondary current return path 154 is available in this fashion at each of the ground straps 148 positioned around the IPVD system 140.

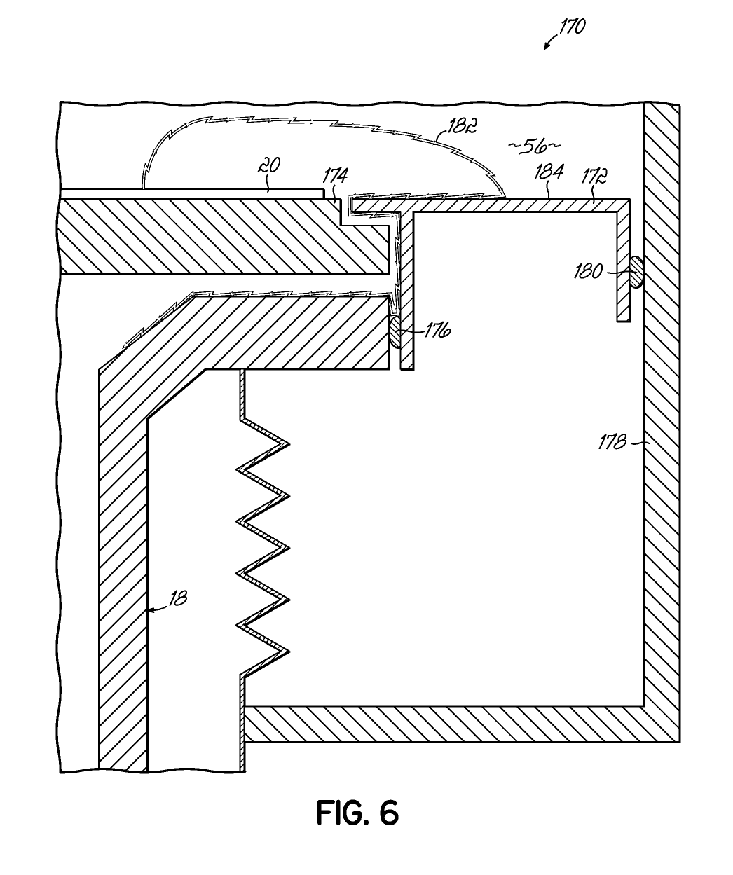

In another embodiment of the IPVD apparatus 170 shown in FIG. 6, the lower chamber shield may be integrated with the table shield. In this embodiment, the integrated shield 172 moves with the chuck 174 as the chuck 174 is raised and lowered to the process and load/unload positions. The integrated shield 172 is in electrical contact with the wafer support system 18 by an RF coupling device 176. The integrated shield 172 is also in electrical contact with the chamber wall 178 through a second RF coupling device 180. As the wafer support system 18 and the integrated shield 172 are raised and lowered, the RF coupling device 180 slides along the chamber wall 178 to maintain an electrical connection between the chamber wall 178 and the integrated shield 172, thus keeping the chamber wall 178, integrated shield 172, and the wafer support system 18 all a the same voltage potential.

Because the shield 172 is integrated in this embodiment, there is a single current return path. RF current leaves the wafer 20 into the plasma in the process volume 56 and contacts the integrated shield 172. The return current path 182 travels along an outer surface 184 of the integrated shield 172 toward the wafer support system 18. The return path 182 travels through the RF coupling device 176 and into the wafer support system 18 to return similar to the embodiments discussed above. If the current contacts the chamber wall 178, the current return path would travel along the wall 178 to RF coupling device 180 where the current would then travel along the same path 182 on the outer surface 184 of the integrated shield 172 to the wafer support system.

The embodiments of the invention discussed above make a low-inductance connection between the lower chamber shield and the table shield, thereby essentially eliminating any potential difference between the two. In this manner, the main mechanism of sustaining a low density plasma in the pumping volume is substantially eliminated.

While the present invention has been illustrated by a description of one or more embodiments thereof and while these embodiments have been described in considerable detail, they are intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. An IPVD source assembly for supplying and ionizing material for coating a semiconductor wafer, the assembly comprising:
a process volume containing a plasma;
a chuck moveable with a table in to and out of the process volume, the chuck configured to support the semiconductor wafer;
a first shield electrically insulated from the chuck and in electrical communication with the table, the first shield configured to shield at least a portion of the chuck when the chuck is in the process volume;
a second shield configured to shield at least a portion of a space below the chuck and the process volume; and
a conducting element electrically connecting the second shield to the table to substantially prevent a formation of a second plasma in the space below the chuck and the process volume.

2. The IPVD source assembly of claim 1 wherein the conducting element is a flexible strap.

3. The IPVD source assembly of claim 2 wherein the flexible strap is composed of copper.

4. The IPVD source assembly of claim 2 wherein the flexible strap is about 100 mm wide.

5. The IPVD source assembly of claim 1 wherein the conducting element is a first conducting element, IPVD source assembly further comprising:
a second conducting element electrically connecting the second shield to the table to substantially prevent a formation of a second plasma in the space below the chuck and the process volume, the second conducting element spaced apart from the first conducting element.

6. The IPVD source assembly of claim 5 wherein the first and second conducting elements are symmetrically spaced apart.

7. The IPVD source assembly of claim 1 wherein the first shield is in electrically communication with the table through an RF coupling device.

8. The IPVD source assembly of claim 1 further comprising:
a base in electrical communication with the table and the conducting element.

9. The IPVD source assembly of claim 8 further comprising:
a support ring in electrical communication with the second shield and the conducting element, the support ring spaced from the base.

10. The IPVD source assembly of claim 9 wherein the support ring is in electrical communication with the second shield through an RF coupling device.

11. The IPVD source assembly of claim 9 wherein the support ring maintains electrical contact for the electrical communication and is spaced from the base by a spring.

12. The IPVD source assembly of claim 9 further comprising:
a third shield in electrical communication with the base, the third shield in electrical communication with an extension of the support ring through an RF coupling device.

13. An IPVD source assembly for supplying and ionizing material for coating a semiconductor wafer, the assembly comprising:
a process volume containing a plasma;
a chuck moveable in to and out of the process volume, the chuck configured to support the semiconductor wafer; and
a shield in electrical communication with a table and with a chamber wall defining a portion of the process volume, the shield configured move in to and out of the process volume with the chuck and to shield at least a portion of the chuck when the chuck is in the process volume;
the shield further configured to shield at least a portion of a space below the electrostatic chuck and the process volume and substantially prevent a formation of a second plasma in the space below the chuck and the process volume.

14. The IPVD source assembly of claim 13 wherein the shield is in electrical communication with the table through an RF coupling device.

15. The IPVD source assembly of claim 13 wherein the shield is in electrical communication with the chamber wall through an RF coupling device.

16. A method of substantially preventing formation of a plasma in a pumping volume, the method comprising:
providing electrical connection between a chamber shield that surrounds a wafer support to reduce a potential difference between different return RF current paths.

17. The method of claim 16 wherein providing the electrical connection includes:
electrically connecting a first shield to a table; and
electrically connecting a second shield to the table to substantially prevent a formation of a potential difference between the first and second shields,
wherein a first RF current return path forms along a surface of the first shield to a surface of the table, and
wherein a second RF current return path forms along a surface of the second shield to a surface of the table.

18. The method of claim 17 wherein the first current return path forms between surface of the first shield and the surface of the table through an RF coupling device.

19. The method of claim 17 wherein the second current return path forms along a conducting element electrically connecting the surface of the second shield to the surface of the table.

20. The method of claim 19 wherein the second current return path further forms along a surface of a base between the conducting element and the surface of the table.

21. The method of claim 16 wherein providing the electrical connection includes:
electrically connecting a shield to a table and to a chamber wall to substantially prevent a formation of a potential difference between the shield and the chamber wall,
wherein a first RF current return path forms along a surface of the shield to a surface of the table, and
wherein a second RF current return path forms along a surface of the chamber wall the surface of the shield then to the surface of the table.
